(19) United States
(12) Patent Application Publication
(10) Pub. No.: US 2026/0310104 A1
(43) Pub. Date: Oct. 8, 2026

(54) REPEATING NOISE SUPPRESSION FOR ARRAY PRINT CHECK INSPECTION

(71) Applicant: KLA Corporation, Milpitas, CA (US)

(72) Inventors: Hucheng Lee, Cupertino, CA (US); Hsiao-Min Wang, Taoyuan City (TW); Jusang Maeng, Seoul (KR); Heonju Shin, Gyeonggi-do (KR)

(21) Appl. No.: 19/235,543

(22) Filed: Jun. 11, 2025

Related U.S. Application Data
(60) Provisional application No. 63/782,666, filed on Apr. 3, 2025.

(51) Int. Cl. G03F 7/00

(52) U.S. Cl. CPC G03F 7/7065; G03F 7/70655

(57) ABSTRACT

Systems and methods for detecting defects on a reticle are provided. The embodiments are particularly advantageous for noise suppression in array print check type reticle inspections. The embodiments reduce noise in inspection images by interpolating images of a wafer printed with a reticle when a pitch of patterned features in the images is not an integer of pixels in a detector of an inspection subsystem that generates the images. The systems and methods may also reduce noise by dynamic compensation of the images that are compared to each other to generate difference images. The embodiments further reduce noise by stacking difference images for multiple instances of a care area, detecting defects on the wafer in the stacked difference images, and then using the detected wafer defects to detect defects on the reticle. By reducing noise and particularly repeating noise, repeating defects on reticles can be detected with higher signal-to-noise ratios.

### BACKGROUND OF THE INVENTION

### 1. Field of the Invention

The present invention generally relates to systems and methods for repeating noise suppression for array print check type inspection of reticles, which provide better detection of repeaters on reticles via multiple types of noise suppression.

### 2. Description of the Related Art

The following description and examples are not admitted to be prior art by virtue of their inclusion in this section.

Inspection processes are used at various steps during a semiconductor manufacturing process to detect defects on wafers to promote higher yield in the manufacturing process and thus higher profits. Some current inspection methods detect repeater defects on wafers to thereby detect defects on reticles. For example, if a defect is detected repeatedly (“a repeater defect”) at multiple locations on a wafer corresponding to the same location on a reticle, the defects may be caused by the reticle itself. Therefore, repeater defects may be analyzed to determine if they are caused by reticle defects, rather than some other cause.

In general, repeater defect detection (RDD) is performed as a wafer post-processing (PP) operation. For example, the inspection tool may perform normal defect detection (DD), and after all wafer defects are reported, the RDD may be performed in a post-processing step. The repeater defects are defined in this filing as defects positioned at the same location (within a certain tolerance) in several instances of the same care area (CA).

There are, however, several disadvantages to the currently used methods and systems for RDD. For example, many currently used RDD methods and systems have been created to try to reduce noise so that repeater defects can be detected more accurately, with fewer detected nuisances, and with higher sensitivity. One example of a currently used method for logic area inspection aims to catch repeaters on reticles by using image stacking to reduce a considerable amount of noise compared to other die-to-die type inspections normally used for logic area inspection and thereby help to catch more repeaters. To inspect repeaters in an array area with this same method, array areas have to be defined as random regions to gain the power of image stacking. Otherwise, process of record (POR) array mode will be used, and different images of individual frames are not stacked to further reduce random noise. However, when array areas are defined as random regions, repeating noise is still observed in array areas which makes weak repeaters not stand out from non-defective data enough to be detected and leads to defects of interest (DOIs) being missed.

Accordingly, it would be advantageous to develop systems and methods for detecting defects on a wafer and thereby defects on a reticle that do not have one or more of the disadvantages described above.

### SUMMARY OF THE INVENTION

The following description of various embodiments is not to be construed in any way as limiting the subject matter of the appended claims.

One embodiment relates to a system configured for detecting defects on a reticle. The system includes an inspection subsystem configured for generating images of patterned features formed in an array region on a wafer. A reticle is used to print the patterned features on the wafer in a lithography process. The system also includes a computer subsystem configured for, when a pitch of the patterned features in an instance of a care area (CA) in the images is not an integer of pixels in a detector of the inspection subsystem, interpolating a portion of the images in the instance of the CA to generate an interpolated CA image having a modified pitch of the patterned features in the interpolated CA image that is an integer of the pixels.

The computer subsystem is also configured for generating difference images for multiple instances of the CA in the images. Generating at least one of the difference images includes subtracting the interpolated CA image from an additional portion of the images in at least one of the multiple instances of the CA. The computer subsystem is further configured for stacking the difference images to generate a stacked difference image, detecting defect candidates in the CA by applying a defect detection method to the stacked difference image, and identifying defects on the reticle based on the detected defect candidates. The system may be further configured as described herein.

Another embodiment relates to a computer-implemented method for detecting defects on a reticle. The method includes acquiring images of patterned features formed in an array region on a wafer generated by an inspection subsystem. A reticle is used to print the patterned features on the wafer in a lithography process. The method also includes the interpolating, generating, stacking, detecting, and identifying steps described above, which are performed by a computer system coupled to the inspection subsystem. Each of the steps of the method may be further performed as described herein. The method may include any other step(s) of any other method(s) described herein. The method may be performed by any of the systems described herein.

Another embodiment relates to a non-transitory computer-readable medium storing program instructions executable on a computer system for performing a computer-implemented method for detecting defects on a reticle. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIGS. 1 and 2 are schematic diagrams illustrating side views of embodiments of a system configured as described herein;

FIG. 3 is a flow chart illustrating an embodiment of steps that may be performed for detecting defects on a reticle;

FIG. 4 is a schematic diagram illustrating examples of difference images generated by a currently used method and the embodiments described herein;

FIG. 5 is a schematic diagram illustrating examples of stacked difference images generated by a currently used method and the embodiments described herein;

FIG. 6 is a schematic diagram illustrating examples of plots generated by a defect detection method with a currently used method and the embodiments described herein;

FIG. 7 is a schematic diagram illustrating a plan view of one example of a portion of a wafer that includes array regions repeating in orthogonal dimensions on the wafer;

FIG. 8 is a schematic diagram illustrating a plan view of one example of a portion of a wafer that includes an array region that is repeating in orthogonal dimensions on the wafer; and

FIG. 9 is a block diagram illustrating one embodiment of a non-transitory computer-readable medium storing program instructions executed on a computer system for performing one or more of the computer-implemented methods described herein.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

One embodiment relates to a system configured for detecting defects on a reticle. The embodiments described herein provide new and improved methods and systems for repeating noise suppression for array print check type inspections of reticles. The embodiments advantageously reduce repeating noise of array region images by mitigating cell-to-cell color variation followed by image stacking. The terms “reticle” and “mask” are used interchangeably herein. The term “repeaters” is used interchangeably herein with the term “repeater defects.”

“Care areas” as they are commonly referred to in the art are areas on a specimen that are of interest for inspection purposes. Sometimes, care areas (CAs) are used to differentiate between areas on the specimen that are inspected from areas on the specimen that are not inspected in an inspection process. In addition, CAs are sometimes used to differentiate between areas on the specimen that are to be inspected with one or more different parameters. For example, if a first area of a specimen is more critical than a second area on the specimen, the first area may be inspected with a higher sensitivity than the second area so that defects are detected in the first area with a higher sensitivity. Other parameters of an inspection process can be altered from CA to CA in a similar manner.

The term “defects of interest (DOIs)” as used herein is defined as defects that are detected on a specimen and are really actual defects on the specimen. Therefore, the DOIs are of interest to a user because users generally care about how many and what kind of actual defects are on specimens being inspected. In some contexts, the term “DOI” is used to refer to a subset of all of the actual defects on the specimen, which includes only the actual defects that a user cares about. For example, there may be multiple types of DOIs on any given specimen, and one or more of them may be of greater interest to a user than one or more other types. In the context of the embodiments described herein, however, the term “DOIs” is used to refer to any and all real defects on a specimen.

“Nuisances” (which is sometimes used interchangeably with “nuisance defects”) as that term is used herein is generally defined as defects that a user does not care about and/or events that are detected on a specimen but are not really actual defects on the specimen. Nuisances that are not actually defects may be detected as events due to non-defect noise sources on a specimen (e.g., grain in metal lines on the specimen, signals from underlaying layers or materials on the specimen, line edge roughness (LER), relatively small critical dimension (CD) variation in patterned attributes, thickness variations, etc.) and/or due to marginalities in the inspection system itself or its configuration used for inspection.

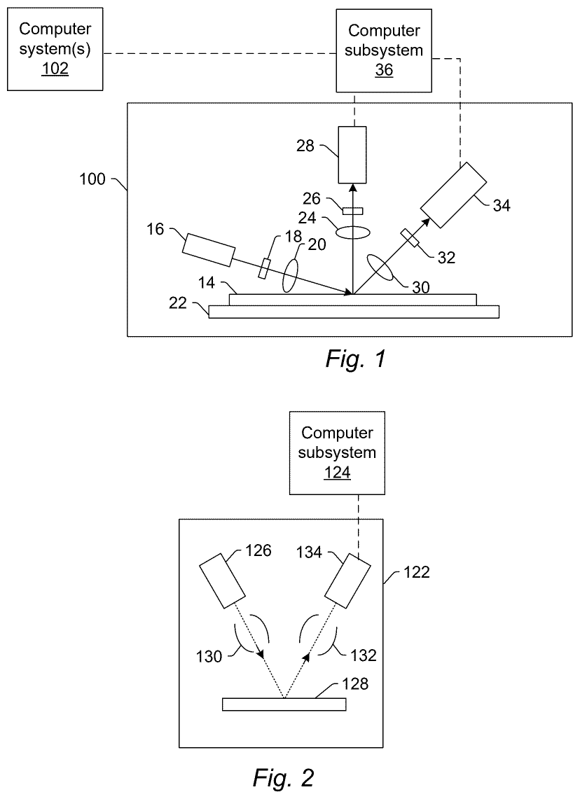

One embodiment of a system configured for detecting defects on a reticle is shown in FIG. 1. The system includes an inspection subsystem configured to generate images of patterned features formed in an array region on a wafer. The embodiments described herein may be performed for any reticle and with any wafer known in the semiconductor arts. The inspection subsystems described herein may include at least an energy source and a detector. The energy source is configured to generate energy that is directed to a wafer. The detector is configured to detect energy from the wafer and to generate images responsive to the detected energy.

The system shown in FIG. 1 includes inspection subsystem 100. In this embodiment, the inspection subsystem is configured as a light-based inspection subsystem. However, in another embodiment, the inspection subsystem may be configured as an electron beam or charged particle beam based inspection subsystem.

In a light-based inspection subsystem, the energy directed to the wafer includes light, and the energy detected from the wafer includes light. For example, as shown in FIG. 1, the inspection subsystem includes an illumination subsystem configured to direct light to wafer 14. The illumination subsystem includes at least one light source, e.g., light source 16. The illumination subsystem is configured to direct the light to the wafer at one or more angles of incidence, which may include one or more oblique angles and/or one or more normal angles. For example, as shown in FIG. 1, light from light source 16 is directed through optical element 18 and then lens 20 to wafer 14 at an oblique angle of incidence. The oblique angle of incidence may include any suitable oblique angle of incidence, which may vary depending on, for instance, characteristics of the wafer and the defects to be detected on the wafer.

The illumination subsystem may be configured to direct the light to the wafer at different angles of incidence. For example, the inspection subsystem may be configured to alter one or more characteristics of one or more elements of the illumination subsystem such that the light can be directed to the wafer at an angle of incidence that is different than that shown in FIG. 1. In one such example, the inspection subsystem may be configured to move light source 16, optical element 18, and lens 20 such that the light is directed to the wafer at a different oblique angle of incidence or a normal (or near normal) angle of incidence. The illumination subsystem may have any other suitable configuration known in the art for directing the light to the specimen at one or more angles of incidence sequentially or simultaneously.

The illumination subsystem may also be configured to direct light with different characteristics to the wafer. For example, optical element 18 may be configured as a spectral filter and the properties of the spectral filter can be changed in a variety of different ways (e.g., by swapping out one spectral filter with another) such that different wavelengths of light can be directed to the wafer at different times.

Light source 16 may include a broadband plasma (BBP) light source. In this manner, the light generated by the light source and directed to the wafer may include broadband light. However, the light source may include any other suitable light source such as any suitable laser known in the art configured to generate light at any suitable wavelength(s) known in the art. In addition, the laser may be configured to generate light that is monochromatic or nearly-monochromatic. In this manner, the laser may be a narrowband laser. The light source may also include a polychromatic light source that generates light at multiple discrete wavelengths or wavebands.

Light from optical element 18 may be focused onto wafer 14 by lens 20. Although lens 20 is shown in FIG. 1 as a single refractive optical element, in practice, lens 20 may include a number of refractive and/or reflective optical elements that in combination focus the light from the optical element to the wafer. The illumination subsystem shown in FIG. 1 and described herein may include any other suitable optical elements (not shown). Examples of such optical elements include, but are not limited to, polarizing component(s), spectral filter(s), spatial filter(s), reflective optical element(s), apodizer(s), beam splitter(s), aperture(s), and the like, which may include any such suitable optical elements known in the art. In addition, the system may be configured to alter one or more of the elements of the illumination subsystem based on the type of illumination to be used for inspection.

The inspection subsystem may also include a scanning subsystem configured to change the position on the wafer to which the light is directed and from which the light is detected and possibly to cause the light to be scanned over the wafer. For example, the inspection subsystem may include stage 22 on which wafer 14 is disposed during inspection. The scanning subsystem may include any suitable mechanical and/or robotic assembly (that includes stage 22) that can be configured to move the wafer such that the light can be directed to and detected from different positions on the wafer. In addition, or alternatively, the inspection subsystem may be configured such that one or more optical elements of the inspection subsystem perform some scanning of the light over the wafer such that the light can be directed to and detected from different positions on the wafer. The light may be scanned over the wafer in any suitable fashion such as in a serpentine-like path or in a spiral path.

The inspection subsystem further includes one or more detection channels. At least one of the detection channel(s) includes a detector configured to detect light from the wafer due to illumination of the wafer by the system and to generate images responsive to the detected light. The inspection subsystem shown in FIG. 1 includes two detection channels, one formed by collector 24, element 26, and detector 28 and another formed by collector 30, element 32, and detector 34. The two detection channels are configured to collect and detect light at different angles of collection. In some instances, both detection channels are configured to detect scattered light, and the detection channels are configured to detect light that is scattered at different angles from the wafer. However, one or more of the detection channels may be configured to detect another type of light from the wafer (e.g., reflected light).

In FIG. 1, both detection channels are shown positioned in the plane of the paper and the illumination subsystem is also shown positioned in the plane of the paper. Therefore, in this embodiment, both detection channels are positioned in (e.g., centered in) the plane of incidence. However, one or more of the detection channels may be positioned out of the plane of incidence. For example, the detection channel formed by collector 30, element 32, and detector 34 may be configured to collect and detect light that is scattered out of the plane of incidence. Therefore, such a detection channel may be commonly referred to as a “side” channel, and such a side channel may be centered in a plane that is substantially perpendicular to the plane of incidence.

Although FIG. 1 shows an embodiment of the inspection subsystem that includes two detection channels, the inspection subsystem may include a different number of detection channels (e.g., only one detection channel or two or more detection channels). The detection channel formed by collector 30, element 32, and detector 34 may form one side channel as described above, and the inspection subsystem may include an additional detection channel (not shown) formed as another side channel that is positioned on the opposite side of the plane of incidence. Therefore, the inspection subsystem may include the detection channel that includes collector 24, element 26, and detector 28 and that is centered in the plane of incidence and configured to collect and detect light at scattering angle(s) that are at or close to normal to the wafer surface. This detection channel may therefore be commonly referred to as a “top” channel, and the inspection subsystem may also include two or more side channels configured as described above. As such, the inspection subsystem may include at least three channels (i.e., one top channel and two side channels), and each of the at least three channels is configured to collect light at different scattering angles than each of the other collectors.

As described further above, one or more of the detection channels may be configured to detect scattered light. Therefore, the inspection subsystem shown in FIG. 1 may be configured for dark field (DF) inspection of wafers. However, the inspection subsystem may also or alternatively include detection channel(s) that are configured for bright field (BF) inspection of wafers. Therefore, the inspection subsystems described herein may be configured for only DF, only BF, or both DF and BF inspection. Although each of the collectors are shown in FIG. 1 as single refractive optical elements, each of the collectors may include refractive optical element(s) and/or reflective optical element(s).

The one or more detection channels may include any suitable detectors known in the art such as photo-multiplier tubes (PMTs), charge coupled devices (CCDs), and time delay integration (TDI) cameras. The detectors may also include non-imaging detectors or imaging detectors. If the detectors are non-imaging detectors, each of the detectors may be configured to detect certain characteristics of the scattered light such as intensity but may not be configured to detect such characteristics as a function of position within the imaging plane. As such, the output that is generated by each of the detectors in each of the detection channels may be signals or data, but not image signals or image data. In such instances, a computer subsystem may be configured to generate images of the wafer from the non-imaging output of the detectors. However, in other instances, the detectors may be configured as imaging detectors that are configured to generate imaging signals or image data. Therefore, the inspection subsystem may be configured to generate images in a number of ways.

Computer subsystem 36 may be coupled to the detectors of the inspection subsystem in any suitable manner (e.g., via one or more transmission media, which may include “wired” and/or “wireless” transmission media) such that the computer subsystem can receive the output generated by the detectors. Computer subsystem 36 may be configured to perform a number of functions using the output of the detectors as described further herein. Computer subsystem 36 may be further configured as described herein.

Computer subsystem 36 (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer subsystem, then the different computer subsystems may be coupled to each other such that images, data, information, instructions, etc. can be sent between the computer subsystems. For example, computer subsystem 36 may be coupled to computer system(s) 102 as shown by the dashed line in FIG. 1 by any suitable transmission media, which may include any suitable wired and/or wireless transmission media known in the art. Two or more of such computer subsystems may also be effectively coupled by a shared computer-readable storage medium (not shown).

Although the inspection subsystem is described above as being an optical or light-based inspection subsystem, the inspection subsystem may be configured as an electron beam based inspection subsystem. In an electron beam inspection subsystem, the energy directed to the wafer includes electrons, and the energy detected from the wafer includes electrons. In one such embodiment shown in FIG. 2, the inspection subsystem includes electron column 122, and the system includes computer subsystem 124 coupled to the inspection subsystem. Computer subsystem 124 may be configured as described above. In addition, such an inspection subsystem may be coupled to another one or more computer subsystems in the same manner described above and shown in FIG. 1.

As also shown in FIG. 2, the electron column includes electron beam source 126 configured to generate electrons that are focused to wafer 128 by one or more elements 130. The electron beam source may include, for example, a cathode source or emitter tip, and one or more elements 130 may include, for example, a gun lens, an anode, a beam limiting aperture, a gate valve, a beam current selection aperture, an objective lens, and a scanning subsystem, all of which may include any such suitable elements known in the art.

Electrons returned from the wafer (e.g., secondary electrons) may be focused by one or more elements 132 to detector 134. One or more elements 132 may include, for example, a scanning subsystem, which may be the same scanning subsystem included in element(s) 130.

The electron column may include any other suitable elements known in the art. In addition, the electron column may be further configured as described in U.S. Pat. No. 8,664,594 issued Apr. 4, 2014 to Jiang et al., 8,692,204 issued Apr. 8, 2014 to Kojima et al., 8,698,093 issued Apr. 15, 2014 to Gubbens et al., and 8,716,662 issued May 6, 2014 to MacDonald et al., which are incorporated by reference as if fully set forth herein.

Although the electron column is shown in FIG. 2 as being configured such that the electrons are directed to the wafer at an oblique angle of incidence and are scattered from the wafer at another oblique angle, the electron beam may be directed to and scattered from the wafer at any suitable angles. In addition, the electron beam inspection subsystem may be configured to use multiple modes to generate images of the wafer as described further herein (e.g., with different illumination angles, collection angles, etc.). The multiple modes of the electron beam inspection subsystem may be different in any image generation parameters of the inspection subsystem.

Computer subsystem 124 may be coupled to detector 134 as described above. The detector may detect electrons returned from the surface of the wafer thereby forming electron beam images of (or other output for) the wafer. The electron beam images may include any suitable electron beam images. Computer subsystem 124 may be configured to perform any step(s) described herein. A system that includes the inspection subsystem shown in FIG. 2 may be further configured as described herein.

FIGS. 1 and 2 are provided herein to generally illustrate configurations of an inspection subsystem that may be included in the system embodiments described herein. Obviously, the inspection subsystem configuration described herein may be altered to optimize the performance of the inspection subsystem as is normally performed when designing a commercial inspection system. In addition, the systems described herein may be implemented using an existing inspection system (e.g., by adding functionality described herein to an existing inspection system) such as the tools that are commercially available from KLA. For some such systems, the methods described herein may be provided as optional functionality of the inspection system (e.g., in addition to other functionality of the inspection system). Alternatively, the inspection system described herein may be designed “from scratch” to provide a completely new inspection system.

Although the inspection subsystem is described above as being a light or electron beam inspection subsystem, the inspection subsystem may be an ion beam inspection subsystem. Such an inspection subsystem may be configured as shown in FIG. 2 except that the electron beam source may be replaced with any suitable ion beam source known in the art. In addition, the inspection subsystem may include any other suitable ion beam system such as those included in commercially available focused ion beam (FIB) systems, helium ion microscopy (HIM) systems, and secondary ion mass spectroscopy (SIMS) systems.

The inspection subsystem may be configured to generate output, e.g., images, of the wafer with multiple modes. In general, a “mode” is defined by the values of parameters of the inspection subsystem used for generating images of a wafer (or the output used to generate images of the wafer). Therefore, modes may be different in the values for at least one of the parameters of the inspection subsystem (other than position on the wafer at which the output is generated). For example, the modes may be different in any one or more alterable parameters (e.g., illumination polarization(s), angle(s), wavelength(s), etc., detection polarization(s), angle(s), wavelength(s), etc.) of the inspection subsystem. The inspection subsystem may be configured to scan the wafer with the different modes in the same scan or different scans, e.g., depending on the capability of using multiple modes to scan the wafer at the same time.

In a similar manner, the electron beam subsystem may be configured to generate images with two or more modes, which can be defined by the values of parameters of the electron beam subsystem used for generating images for a wafer. Therefore, modes may be different in the values for at least one of the electron beam parameters of the electron beam subsystem. For example, different modes may use different angles of incidence for illumination.

As noted above, the inspection subsystem is configured for scanning energy (e.g., light, electrons, etc.) over a physical version of the wafer thereby generating images of the physical version of the wafer. In this manner, the inspection subsystem may be configured as an “actual” subsystem, rather than a “virtual” subsystem. However, a storage medium (not shown) and computer subsystem(s) 102 shown in FIG. 1 may be configured as a “virtual” system. In particular, the storage medium and the computer subsystem(s) may be configured as a “virtual” inspection system as described in commonly assigned U.S. Pat. No. 8,126,255 issued on Feb. 28, 2012 to Bhaskar et al. and 9,222,895 issued on Dec. 29, 2015 to Duffy et al., which are incorporated by reference as if fully set forth herein. The embodiments described herein may be further configured as described in these patents.

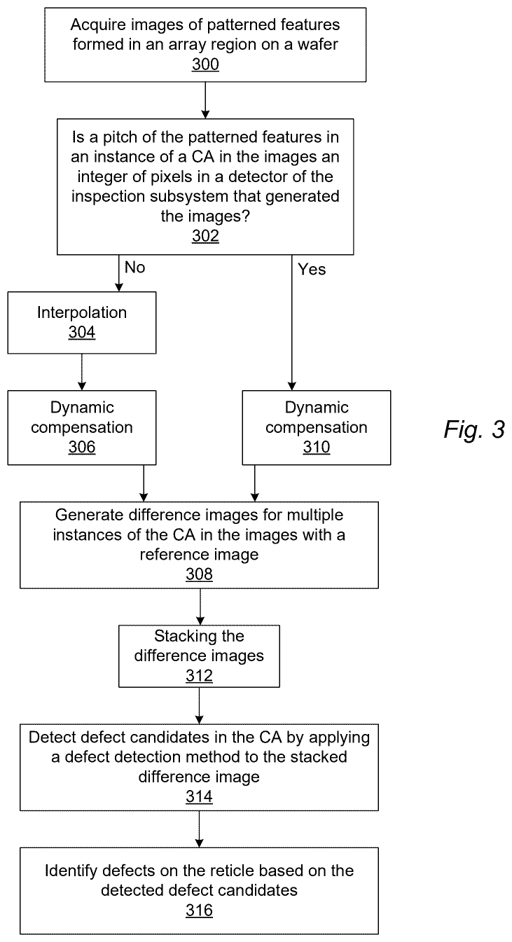

As shown in step 300 of FIG. 3, the computer subsystem may acquire images of patterned features in an array region on a wafer. Acquiring the images may include generating the images with an inspection subsystem configured as described herein. This image acquisition may be done when the computer subsystem and the inspection subsystem are coupled in one tool and possibly when the defect detection described herein is being performed on-tool and/or as the images are being generated. In other instances, the computer subsystem may acquire the images from another method, system, or storage medium. For example, the computer subsystem and the inspection subsystem may or may not be coupled into a single tool, and the inspection subsystem, the computer subsystem, or another computer subsystem may store the images generated by the inspection subsystem. The computer subsystem may then acquire the images from the storage medium in which they are stored. This image acquisition may be done when the computer subsystem performs the steps described herein off-tool and/or after all (or at least some) of the images have been generated. Each of the elements described above may be configured as described and shown further herein.

A reticle is used to print the patterned features on the wafer in a lithography process. The lithography process may include any suitable lithography process. In general, a lithography process uses some form of energy (e.g., light, electrons, etc.) to transfer a pattern formed on a reticle to a material on a wafer. The material on the wafer may be some form of resist, one or more properties of which change after exposure to the energy used in the lithography process. In this manner, a pattern of energy (light, electrons, etc.) can be directed from or through a reticle to a resist on a wafer to thereby transfer the pattern from the reticle to the resist. One or more additional steps may be performed on the resist (e.g., post exposure bake, development, etc.) to complete the pattern transfer process. Therefore, as can be clearly seen from this general description of lithography processes, defects that are present on a reticle can be transferred to a wafer in the lithography process, which is obviously disadvantageous. Sometimes it is not possible or practical to inspect a reticle directly, as in a reticle inspection process. In such instances, the reticle is printed on a wafer, the wafer is inspected for defects, and those wafer defects are used to determine if the defects are caused by the reticle. Such determinations may be performed as described further herein.

The embodiments described herein provide substantially high sensitivity repeater defect detection (RDD) for print check by suppressing repeating noise. “Print check” is defined herein as a type of mask inspection that involves printing the mask on a wafer, inspecting the wafer, and identifying defects on the mask based on the wafer inspection results. Print check may be used for a variety of applications including identifying reticle repeaters for mask qualification and/or monitoring, which may be performed to routinely or regularly check masks released to production for possible contamination.

In one embodiment, the array region forms part of a memory device being fabricated on the wafer. The memory device may include any memory device known in the art including dynamic random access memory (DRAM) devices. The embodiments described herein propose novel detection methods to improve array region sensitivity. The embodiments provide several important improvements over currently used systems and methods for array region inspection, which are discussed in detail further herein.

In one embodiment, the patterned features and the inspection subsystem, in combination, cause the images responsive to the patterned features to have repeating and non-constant intensity. For example, the embodiments described herein provide novel inspection methods and systems for resolvable repeating array regions. In terms of the embodiments described herein, “resolvable repeating patterns” and “resolvable patterned features” does not necessarily mean that the pattern on the wafer is resolvable to the inspection subsystem. In reality, very often, many wafer patterns are only partially resolvable to the inspection subsystem. Instead, in the embodiments described herein, “resolvable” means that the acquired image has repeating and non-constant intensity. In other words, within each unit cell (the basic repeating pattern for array regions), the image gray scale as seen by the inspection subsystem has some variation that is not caused by noise.

As shown in step 302 of FIG. 3, the computer subsystem is configured for determining if a pitch of the patterned features in an instance of a CA in the images is an integer of pixels in a detector of the inspection subsystem that generated the images. The “pitch of the patterned features in the images” is not necessarily the same as the “pitch of the patterned features on the specimen.” For example, for obvious reasons, the pitch of the imaged patterned features can be different than the pitch of the physical patterned features due to the imaging process. The embodiments described herein are primarily concerned with variations in the pitch from an integer of the pixels regardless of the reason for such variations. For example, even if it is possible to create an inspection recipe that would result in the patterned features having a pitch in the images that is an integer of the pixels, variations in the performance of the inspection subsystem can cause the imaged patterned features to have a pitch that is not an integer of the pixels.

Determining if the pitch of the patterned features in the images is an integer of the pixels may be performed in any suitable manner known in the art. The relationship between the pitch of the patterned features and the image pixels may vary from CA-to-CA (e.g., cell-to-cell), which may be caused by, for example, perturbation or drift in the inspection subsystem. Therefore, this determining step may be performed separately and independently for each portion of the images corresponding to a CA in the array region. However, the determining step does not necessarily need to be performed for every CA that is being inspected. For example, the determining step may be performed for the first few CAs to establish a relationship between patterned feature pitch and image pixels, and then the determining step may be performed for every x CAs thereafter. In particular, while checking the patterned feature pitch to image pixels relationship for each CA may be ideal, in the interest of saving time and money, the determining step may be performed for fewer than all of the CAs. The steps described herein that are performed for each of those portions of images may vary then depending on whether or not the pitch of the patterned features in the images is an integer of the pixels.

In another embodiment, the multiple instances of the CA correspond to individual cells in the array region. For example, in the embodiments described herein, each of the CAs may be defined as a single cell in the array region. However, the CAs may be defined as multiple cells in the array region or in some other manner. For example, although each array region CA may most commonly be defined as a single cell in the array region, the embodiments described herein can be used with any array region CA definition.

When repeating areas other than cells are being compared for the defect detection described further herein, the determining step described above may be performed for each of those repeating areas in the same manner. In other words, although the embodiments may be described herein with respect to cell-to-cell detection, the embodiments are not limited to such detection and may be used for defect detection that compares one repeating area to another repeating area. In addition, although the embodiments described herein may be particularly useful for defect detection in array regions, in which all (or nearly all) of the patterned features included therein are designed to have the same pitch, the embodiments described herein are not limited to array region inspection. For example, the determining step described above may be performed using only a portion of the images for a repeating area in which the pitch of the patterned features should be an integer of the pixels. Other steps described further herein, e.g., interpolation and dynamic compensation, may be performed for the entirety of the images generated for that repeating area depending on whether or not the pitch of the patterned features in that portion of the images is an integer of the pixels.

The system also includes a computer subsystem configured for, when a pitch of the patterned features in an instance of a CA in the images is not an integer of pixels in a detector of the inspection subsystem that generated the images, interpolating a portion of the images in the instance of the CA to generate an interpolated CA image having a modified pitch of the patterned features in the interpolated CA image that is an integer of the pixels. For example, when step 302 in FIG. 3 indicates that the pitch of the patterned features is not an integer of the pixels, the computer subsystem performs interpolation step 304. With interpolation, there is no special limitation in the image acquisition step, and interpolation can reduce the complexity of the system and make the system easier to use. In other words, the system does not have to be configured so that the pitch of the patterned features in the images is an integer of the pixels. In addition, if the pitch of the patterned features in the images becomes a non-integer of the pixels for any reason (e.g., perturbation or drift in the tool), the embodiments described herein can still use the images for defect detection (e.g., after the interpolation step has been performed for the images).

Interpolating the images generally may include interpolating the image gray scale intensity although the interpolation may be performed for any aspect of the inspection subsystem images. Interpolating the images may include any suitable type of interpolation known in the art and may be performed in any suitable manner known in the art. For example, while it is important that “interpolation” should give as accurate a result as possible, there are different interpolation methods. The interpolation method used in the embodiments described herein can be selected based on the desired accuracy and throughput for the embodiments compared to the accuracy and throughput of the various interpolation methods known in the art.

In one embodiment, settings of the inspection subsystem used for generating the images are not selected based on a pitch of the patterned features on the wafer or the pitch of the patterned features in the images. For example, in repeating array regions, neighboring cells are used to generate a reference image for a test cell. Usually when the image is acquired, the inspection subsystem is set to make sure the pattern is repeating in the horizontal dimension and the pitch is in integer pixels. In particular, without the embodiments described herein, a user may have to define array CAs and define the cell pitch. The system may then apply zoom to make the cell pitch an integer multiple of pixels. With the embodiments described herein, nominal pixel size can be used and no optical zoom needs to be applied. In this manner, with interpolation, there is no special limitation in the image acquisition step, which can reduce the complexity of the system and make the system easier to use.

In some embodiments, prior to generating the at least one of the difference images, the computer subsystem is configured for dynamic compensation of the interpolated CA image to the additional portion of the images from which it will be subtracted. As shown in FIG. 3, the results of interpolation step 304 may be input to dynamic compensation step 306. In some currently used array inspection methods, a median cell generated from several neighboring cells may be used as a reference image for a test cell. The median operation helps to reduce some noise and variation between neighboring cells. However, it may not be powerful enough to handle cell-to-cell color variation. The embodiments described herein however can remove cell-to-cell gray scale variation by performing dynamic compensation, which reduces noise and improves sensitivity. For example, dynamic compensation may be performed to correct the color variation between cells. In other words, the dynamic compensation reduces the noise (or difference) between test and reference image as much as possible. In one such example, dynamic compensation may be performed by adjusting the gray scale value of a reference image in a systematic way such that the difference between the test and reference images becomes smaller. Dynamic compensation is performed as a part of image processing and may be performed in any suitable manner known in the art.

In one such embodiment, the dynamic compensation reduces differences between the interpolated CA image and the additional portion of the images due to color variation on the specimen. In another embodiment, generating the at least one of the difference images by subtracting the interpolated CA image from the additional portion of the images and the dynamic compensation reduces noise in the at least one of the difference images. For example, dynamic compensation may be used to deal with cell-to-cell color variations by making the reference image more similar to the test image. A better reference image means lower noise in difference images generated with the reference and higher detection sensitivity.

In contrast, some currently used array, cell-to-cell inspection methods aim to reduce cell-to-cell color variation with dynamic compensation among cells. However, in such methods, individual difference images are generated by subtracting a computed reference (CR) from cell images that may or may not be dynamically compensated. While CRs have provided significant advantages for inspection compared to inspection performed with single reference images generated by an inspection subsystem or from a design database for the wafer, generating difference images using the interpolated and dynamically compensated images as reference images provides significantly better noise reduction than CR based methods.

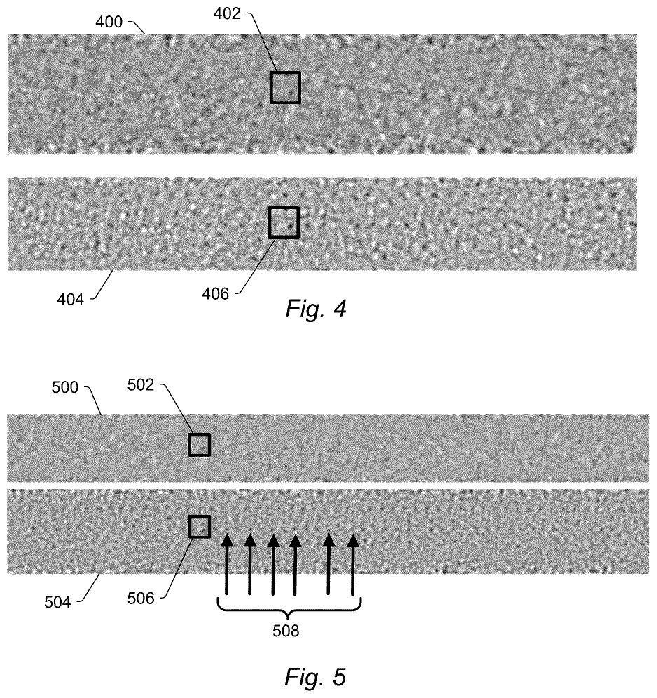

FIG. 4 shows difference images generated with different reference images described above. Difference image 400 is generated by subtracting a reference image (not shown) that has been interpolated and dynamically compensated as described herein from a test image (not shown), and difference image 404 is generated for the same test image with a CR (not shown). As can be seen by comparing difference images 400 and 404 (and especially difference image portions 402 and 406, respectively), a difference image generated using a reference image that has been interpolated and dynamically compensated has significantly less noise than a difference image generated using a CR.

In another embodiment, prior to generating the difference images, the computer subsystem is configured for dynamic compensation of the portion of the images in the instance of the CA to generate a dynamically compensated CA image for the additional portion of the images from which it will be subtracted. For example, the embodiments described herein may perform dynamic compensation for the interpolated image portions as described further above and any image portion that does not need to be interpolated. In other words, the embodiments described herein may perform dynamic compensation for all images used for inspection without exception regardless of whether the images used for defect detection have been interpolated or not.

As shown in FIG. 3, for example, the computer subsystem may perform dynamic compensation step 306 for interpolated images and dynamic compensation step 310 for non-interpolated (or original) images. In general, to simplify the process, the dynamic compensation performed in steps 306 and 310 may be performed in the same manner (e.g., using the same dynamic compensation method or algorithm) although that is not necessary. In addition, although dynamic compensation steps 306 and 310 are shown as separate steps in FIG. 3, the dynamic compensation does not have to be performed separately, and all of the images, interpolated and not, may be input to the same dynamic compensation step. Dynamic compensation 310 may otherwise be performed as described further herein.

In a further embodiment, the dynamic compensation reduces differences between the portion of the images in the instance of the CA and the additional portion of the images from which it will be subtracted due to color variation on the specimen. For example, dynamic compensation step 310 has the same benefits as dynamic compensation step 306 described further above.

The computer subsystem is further configured for generating difference images for multiple instances of the CA in the images, and generating at least one of the difference images includes subtracting the interpolated CA image from an additional portion of the images in at least one of the multiple instances of the CA. For example, as shown in step 308 of FIG. 3, the computer subsystem is configured for generating difference images for multiple instances of the CA in the images with a reference image, and at least one of the reference images used to generate at least one of the difference images is an image corrected as described herein (by interpolation and/or dynamic compensation). The embodiments described herein therefore provide new methods and systems for generating reference images that are then used for difference image generation. In particular, in the embodiments described herein, reference images are generated by the noise reduction step(s) described above and are used to generate difference images, which are then stacked as described herein.

In another embodiment, when the pitch of the patterned features in the additional portion of the images is not an integer of the pixels, the computer subsystem is configured for interpolating the additional portion of the images to generate an additional interpolated CA image having the modified pitch of the patterned features, and generating the at least one of the difference images includes subtracting the interpolated CA image from the additional interpolated CA image. For example, in addition to the image portion designated as the reference image being interpolated and/or dynamically compensated, the image portions designated as the test image may also be corrected by interpolation. In other words, reducing the noise in both the test and reference images by the interpolation and/or dynamic compensation described herein may have greater benefits for defect detection than just correcting one of the images.

Generating the difference images with any of the images described herein may include image alignment and then subtracting one of the images from the other. The image alignment and subtraction may be performed in any suitable manner. In other words, the test and reference images described herein may be used for generating the difference images in the same manner as any other images currently used for difference image generation.

The computer subsystem is also configured for stacking the difference images to generate a stacked difference image, as shown in step 312 of FIG. 3. Although it may be advantageous to use as many difference images as possible (i.e., all of them) to generate a stacked difference image, fewer than all of the difference images may be used to generate a stacked difference image when appropriate (e.g., when one or more of the difference images clearly contain some outlying characteristics). Combining at least a portion of multiple difference images to generate these and any other stacked difference images described herein may otherwise be performed in any suitable manner known in the art. For example, any suitable mathematical operation such as a linear combination may be used to combine multiple difference images into a stacked difference image.

In an additional embodiment, generating the at least one of the difference images by subtracting the interpolated CA image from the additional portion of the images and the dynamic compensation reduces repeating noise in the stacked difference image. For example, some currently used array region inspection methods generate individual difference images for each die with CR images. Once individual difference images are generated, the currently used methods may stack them to get stacked difference images. Defect detection can then be executed on the stacked difference images. In contrast, in the embodiments described herein, individual difference images are generated but with the reference images corrected as described herein (with interpolation and/or dynamic compensation), the difference images are stacked to get stacked difference images, and defect detection is performed on the stacked difference images. As shown in FIG. 5, stacked difference image 500 generated by the embodiments described herein has significantly less noise than stacked difference image 504 generated by the currently used method. In particular, portion 502 of stacked difference image 500 has significantly less noise than corresponding portion 506 of stacked difference image 504. In addition, stacked difference image 504 includes repeating random noise shown at locations 508 in FIG. 5, which may be erroneously detected as defects in any defect detection performed with that stacked difference image.

In a further embodiment, generating the at least one of the difference images by subtracting the interpolated CA image from the additional portion of the images and the dynamic compensation increases signal-to-noise ratio (SNR) of repeating defects in the stacked difference image. For example, by reducing the noise and particularly the repeating noise in the stacked difference images as described herein, the SNR of defects and particularly repeating defects in the stacked difference images will necessarily increase.

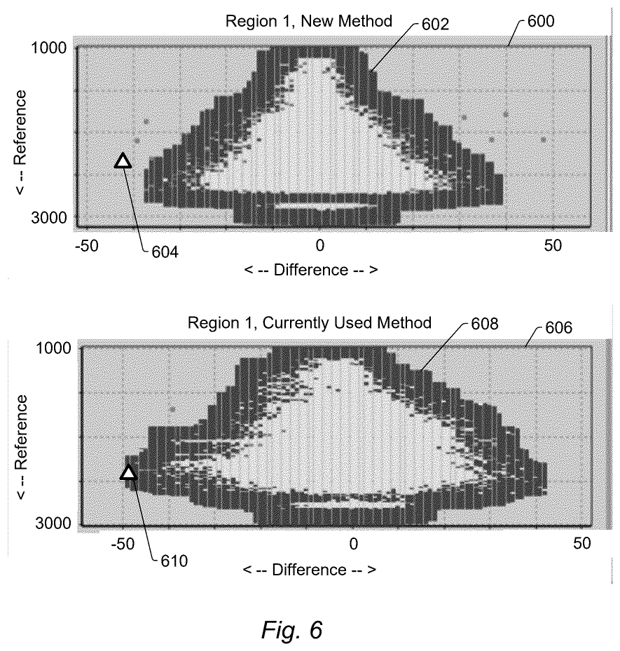

FIG. 6 shows this benefit by comparing defect detection results for one array region on one wafer generated with the embodiments described herein and a currently used method. In particular, FIG. 6 shows a comparison of multi-die auto-thresholding (MDAT) cloud 602 in plot 600 generated with the embodiments described herein and MDAT cloud 608 in plot 606 generated with a currently used method. Each of the MDAT clouds are generated, in this instance, by plotting SNR of stacked difference image pixels as a function of SNR of corresponding reference image pixels. Signal 604 for a repeating DOI stands out of MDAT cloud 602 generated with the embodiments described herein, and signal 610 for the same repeating DOI is buried inside of the MDAT cloud generated with the currently used method. Therefore, the repeating DOI can be detected with the embodiments described herein but not with the currently used method.

In particular, the embodiments described herein provide brand new noise suppression methods for array print check inspection by using the image correction (e.g., interpolation and/or dynamic compensation) as pre-processing step(s) of difference image stacking for array regions. The new approaches described herein reduce repeating noise and make defect signals stand out of the MDAT cloud. In addition, because of the noise reduction capability of the embodiments described herein for array regions, the embodiments will be able to catch weak repeaters that the currently used methods miss. As such, the embodiments described herein have significant and important advantages and improvements over the currently used methods for repeater array region defect detection. In addition, although advantages of the embodiments are described herein with respect to defect detection performed with MDAT, a defect detection algorithm used by some inspection tools that are commercially available from KLA, the embodiments described herein will have similar advantages for any other defect detection method and/or algorithm known in the art.

The computer subsystem is also configured for detecting defect candidates in the CA by applying a defect detection method to the stacked difference image, as shown in step 314 of FIG. 3. Any signals or pixels in the stacked difference image having a value above the threshold may be determined to be a defect candidate (conversely, signals or pixels having a value less than the threshold may not be identified as potential defects). Obviously, this is perhaps the most simple method that can be used for the detection step, and more complex or sophisticated methods may be used. For example, MDAT clouds may be generated as shown in FIG. 6 and defect detection thresholds may be applied to them to detect defects in the stacked difference images. The stacked difference images generated as described herein can be input and used for defect detection in the same manner as any other difference images known in the art. In other words, the stacked difference images described herein are not limited to any kind of defect detection.

In one embodiment, the defect detection method determines that a defect candidate is present at a location in the instance of the CA and the at least one of the multiple instances of the CA only when the defect detection method detects the defect candidate at the location in the stacked difference image. In other words, the defect detection described herein may only be performed with stacked difference images. Individual difference images may not be used for defect detection. The reason for performing defect detection with only the stacked difference images is that the stacked difference images will have much lower noise and higher SNR for the repeating array region defect detection for which the embodiments described herein have been created. In other words, because the stacked difference images are better for defect detection, the embodiments may have no reason to use the individual difference images for defect detection. The original images, the corrected individual images (corrected by interpolation and/or dynamic compensation), and the individual difference images may however be used for any other steps described herein and/or for any other reason known in the art.

The embodiments described herein are also not limited in the type of defect detection that can be performed for any one CA image. For example, although single detection type inspection has been described so far, the embodiments may also be configured for double detection using two stacked difference images generated for one CA image. Double detection generally means that a test image is compared to two different references to generate two different difference images, defect detection is performed on both difference images, and then arbitration is performed so that only defects detected at the same location by both defect detections are reported in the defect detection results. In the embodiments described herein, the computer subsystem may be configured to perform double detection using first and second stacked difference images. The first stacked difference images are generated by stacking difference images, which are individually generated with a first reference CA image generated as described herein, and the second stacked difference images may be generated by stacking difference images, which are separately generated with a second reference CA image also generated as described herein but from different CA image(s) than the first reference CA image. Defect detection may then be separately performed as described herein on the first and second stacked difference images. Arbitration may be performed on the defect detection results in any suitable manner known in the art.

The output of the detection step may be defect detection results, in which a location of any detected defect candidate is identified in each of the CA instances whose difference images were stacked and resulted in the detected defect candidate. In this manner, the output of the detection step may be a full correlation for the defect candidates reported, with no individual frame information. In other words, because detection is performed on the stacked difference image, the computer subsystem cannot determine whether each individual difference image contains a defect candidate based on only the results of the detection step. So when the computer subsystem detects a defect candidate at a location via detection, the computer subsystem will assign a defect candidate at the corresponding location (or flag the location or something equivalent) in each of the difference images used to generate the stacked difference image. Additional steps described herein may then be performed to determine if a defect is at the location of a defect candidate in each of the difference image, and therefore test image, locations.

Any number of defect candidates may be detected by the detection step. Each of the detected defect candidates may then be individually or separately evaluated to determine which of the test images actually contain a defect at the location of a detected defect candidate. The results of the detection step may be reported in any suitable file and format known in the art.

When a wafer is loaded onto an inspection tool with a fixed orientation, some patterns are repeating along the x dimension only. Some patterns are repeating along the y dimension only. Some patterns may also repeat along both the x and y dimensions. The dimensions across which the patterns on a wafer repeat is wafer dependent and may vary depending on the design for the wafer. The embodiments described herein have several advantages for wafers that have patterns repeating in two orthogonal dimensions. When an inspection recipe is being setup, a user may indicate whether a pattern is repeating in x, y, or both x and y. The embodiments described herein can then handle different repeating patterns in the same pass or even simultaneously.

In some embodiments, the array region is repeating in a first dimension on the wafer, an additional array region is repeating in a second dimension on the wafer orthogonal to the first dimension, the computer subsystem is configured for separately performing the interpolating, generating, stacking, and detecting steps for the array region and the additional array region, and the interpolating, generating, stacking, and detecting steps are performed for the array region and the additional array region using the images generated in a single pass of the wafer by the inspection subsystem. In this way, the embodiments can support both horizontally and vertically repeating array patterns.

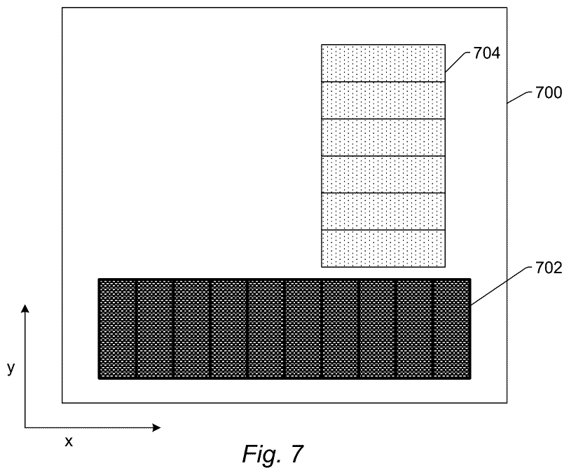

FIG. 7 shows one hypothetical and non-limiting example of portion 700 of a wafer on which array regions 702 and 704 are formed. Array region 702 is repeating in a first dimension, the x dimension, on the wafer, and array region 704 is repeating in a second dimension, the y dimension, on the wafer that is orthogonal to the first dimension. For example, if you consider each of the rectangular regions shown in each of the array regions as a repeating area, then the repeating areas in array region 702 repeat in the x dimension, and the repeating areas in array region 704 repeat in the y dimension. The array regions may also be different in ways other than just the dimensions that they repeat in. For example, array regions 702 and 704 may include different types of patterned features or the same types of patterned features but with one or more different characteristics like size and/or pitch.

Generally speaking though, even if array regions 702 and 704 include the same types of patterned features having all of the same characteristics, the images of the array regions cannot be compared to each other for defect detection because they repeat in different dimensions. In the embodiments described herein, however, the inspection subsystem may generate images for both of the array regions in the same pass of the wafer. In other words, the inspection subsystem does not stop or pause scanning and reposition or re-orient the wafer after one of the array regions has been scanned and before the other array region is scanned. Instead, the images generated for the different array regions in the same scan may be processed separately and independently in other steps described herein. For example, the interpolation, dynamic compensation, and other steps may be performed for one of the array regions using only the images generated for that array region. The interpolation, dynamic compensation, and other steps may then be performed for only the other array region using only the images generated for that other array region. These steps may, however, be performed as described further herein regardless of the array region that they are being performed for.

One of the benefits of this capability is that the proposed embodiments do not have array direction limitations. If a wafer has two array regions repeating in different dimensions, with the embodiments described herein, the system does not need to do 2-pass inspection with two different wafer orientations as in currently used systems and methods. The system can finish inspection of two array regions in the same pass, which means the throughput can be 2× compared to currently used systems and methods. The defects detected in different array regions may be reported separately or collectively depending on the preference of the user.

In this manner, with the interpolation step described herein, the embodiments can inspect horizontal and vertical repeating patterns simultaneously in 1 scan pass, which improves throughput by 2×. A DRAM wafer is a good example of why this is useful. For example, one array region may be a sense amplifier (SA) region of a DRAM array, and another array region may be a sub-word line driver (SWD) region of the DRAM array. In particular, a DRAM wafer usually has repeating SA and SWD regions. However, SA and SWD are always orthogonal to each other. In currently used systems and methods, such a wafer is loaded, one of those regions is inspected, the wafer is then unloaded and rotated followed by inspection of the other region. In the embodiments described herein, however, inspection of the SA and SWD regions can be performed in 1 pass as long as the optical mode permits doing so. In other words, as long as the images for inspection of both regions can be generated in the same pass, whether that means using only a single mode or multiple modes simultaneously, the regions repeating in orthogonal directions can be inspected with those images by the embodiments described herein.

In another embodiment, the array region is repeating in a first dimension on the wafer and a second dimension on the wafer orthogonal to the first dimension, generating a second of the difference images includes subtracting a second CA image in the images for a second of the multiple instances of the CA from the additional portion of the images, the instance of the CA and the at least one of the multiple instances of the CA repeat in the first dimension, and the second of the multiple instances of the CA and the at least one of the multiple instances of the CA repeat in the second dimension. In this way, the embodiments can support both horizontally and vertically repeating array patterns.

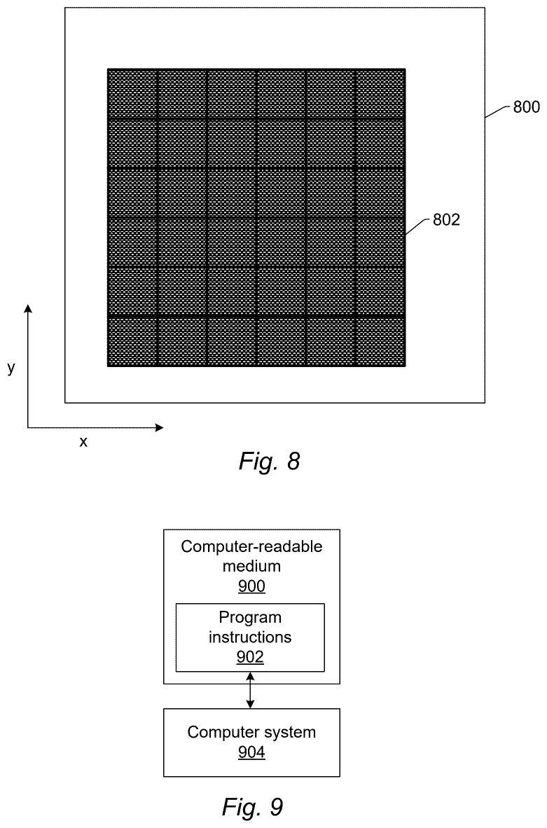

In one such example, FIG. 8 shows one hypothetical and non-limiting example of portion 800 of a wafer on which array region 802 is formed. Array region 802 is repeating in a first dimension, the x dimension, on the wafer, and a second dimension, the y dimension, on the wafer that is orthogonal to the first dimension. For example, if you consider each of the square regions shown in array region 802 as a repeating area, then the repeating areas in array region 802 repeat in the x and y dimensions.

For such an array region, the defect detection performed by the embodiments described herein may include comparing the image (interpolated or not) generated for a first of the repeating areas (e.g., a cell) with at least one other repeating area to the left and/or right of it and comparing the image (interpolated or not) for the first of the repeating areas with at least one other repeating area above and/or below it. Each of these comparisons may include subtracting the reference image (from a repeating area other than the first repeating area) from the test image for the first repeating area to thereby generate a difference image, which may otherwise be performed as described herein. In this manner, multiple difference images may be generated for the same CA image using reference images that are for CAs that repeat with the test CA in different dimensions.

At least one of the reference images used for any one CA image and any one dimension may be generated as described herein (e.g., via interpolation and/or dynamic compensation). For example, for a test cell in the first row of cells repeating in the x dimension, a reference cell may be generated as described herein from another cell also in the first row. A reference image may or may not be generated for the second comparison (in the second repeating dimension) in the same manner. For example, for a test cell in the first column of cells repeating in the y dimension, a median reference cell may be generated from all of the other cells in that first column. Alternatively, for a test cell in the first column of cells repeating in the y dimension, a single, adjacent cell in the first column may be used as the reference cell. In this manner, the reference images used for the comparisons performed for different repeating dimensions may or may not be generated in the same way. Other parameters of defect detection performed for cells repeating in different dimensions may also be different or the same.

For any one CA image, individual difference images generated for that CA and other CAs along one dimension may be stacked to generate a first stacked difference image, and individual difference images generated for that CA image and other CAs along the other dimension may be stacked to generate a second stacked difference image. These stacked difference images may be generated as described further herein. Double detection may then be performed for the one CA image using both stacked difference images.

In one such embodiment, the defect detection method includes determining that a defect is present at a location in the one CA only when both stacked difference images indicate the presence of the defect at the location. In this manner, the embodiments described herein can be configured for double detection in which each detection is performed in a different repeating dimension. For example, as described above, a first stacked difference image may be generated for a test cell and at least one other cell that repeats in a first dimension, and a second stacked difference image may be generated for the test cell and at least one other cell that repeats in a second dimension. A threshold may then be applied to both of the first and second stacked difference images. A defect may be reported at a location in the test cell only when the first and second stacked difference images have values above the threshold at a corresponding location. One of the benefits of this capability is that when array regions repeat in horizontal and vertical dimensions simultaneously, the proposed embodiments can generate two reference images, two difference images, and two stacked difference images by making use of the horizontal and vertical repeatability. Double detection can be used, and nuisance can be further suppressed.

The computer subsystem is further configured for identifying defects on the reticle based on the detected defect candidates, as shown in step 316 of FIG. 3. As described further herein, when a defect candidate is detected, a defect candidate is initially identified in each of the CA images for which the detection was performed (each of the CA images whose individual difference images were stacked). However, a defect may not actually be located at the defect candidate location in each CA image. The computer subsystem may perform a step or steps to first determine if a defect is located at the defect candidate location in each CA image and to then determine if the defect sufficiently repeats in multiple instances of a patterned area to be considered a reticle defect. These steps may be performed as described further herein based at least partially on some local characteristic of the CA images at the locations of the detected defect candidates.

In one embodiment, identifying the defects on the reticle includes identifying repeater defects on the reticle based on the detected defect candidates. In some embodiments, identifying the defects on the reticle includes determining a local image characteristic at a location of one of the detected defect candidates in the images of the multiple instances of the CA, comparing the determined local image characteristic at the location in the images of the multiple instances of the CA to a threshold, determining a number of the images of the multiple instance of the CA having the determined local image characteristic above the threshold, and comparing the determined number to a repeater threshold. For example, the defect detection results generated in any manner described above may be input to the identifying step.

The computer subsystem may then calculate a local image characteristic. For example, the computer subsystem may calculate a local SNR for each defect candidate location in the results. More specifically, the computer subsystem may calculate a local SNR for each defect candidate location in each test image. Although some embodiments may be described herein with respect to a local SNR, the embodiments may use any other suitable local image characteristic or metric for this step including, but not limited to, magnitude, spot likeness, local salience, energy parameter, repeater signal, etc. Any of these local image characteristics may be determined in any suitable manner known in the art.

The computer subsystem may compare the local image characteristic determined at the location in each of the images of the multiple instances of the CA to a threshold (essentially a defect detection threshold). The results of this step may include different indicia that indicate that the defect candidate location in a test image has a local image characteristic above the threshold vs. below the threshold.

The computer subsystem may also perform nuisance filtering by local image characteristic thereby producing defect detection results. In one such example, nuisance filtering may include eliminating any defect candidates having a local SNR below the threshold and retaining any defect candidates having a local SNR above the threshold. In this manner, results of the nuisance filtering step is a partial correlation for the defects reported. What a partial correlation for the defects reported means in this context is that the local SNR test does not need to pass on every test image for a defect to be reported. At least some of the test images have to pass the local SNR test to be considered a repeater defect, and how many of the test images have to pass to be considered a repeater defect is controlled by the repeater threshold. The repeater threshold may be set in advance by a user or in another suitable manner and may vary depending on a number of variables such as the level of process variation expected across the wafer, which may cause a defect to repeat in fewer than all of the test images and/or may cause noise in the test images that can be erroneously detected as defects. Therefore, even if a defect does not repeat at every instance of a test image, under the right circumstances, it may be appropriate to consider it a repeater defect.

The final repeater defect candidates (i.e., defects that repeat in numbers greater than the repeater threshold) may all be identified as defects on the reticle. However, identifying the defects on the reticle based on the final repeater defect candidates may optionally include some additional analysis. For example, the repeaters may be input to any suitable post-processing known in the art such as defect classification (e.g., via any suitable defect classification method or algorithm). Repeater analysis may also include sampling defects for review, which may be performed on a subset of all of the final repeater defect candidates to verify and/or classify the sampled defects. Such review sampling may generate review samples that include information for the selected subset of the final repeater defect candidates, which can then be sent to a defect review tool (not shown) that performs the defect review.

In general, the embodiments described herein are configured for detecting reticle repeater defects, but some of the reticle repeater defects may actually be die repeater defects. For the purpose of the applications described herein, the user may want to keep only reticle repeaters. In particular, the embodiments described herein may be used for applications in which the user is looking for the repeater defects that are produced due to problems with the reticle (photomask). In that case, defects that are present at the same location in different dies on the same reticle are, most likely, caused by wafer processing—not by the reticle itself.

In other words, defects that appear on the wafer at substantially the same location in multiple dies of a single reticle are likely not due to actual reticle defects such as a damaged patterned feature, a particle or foreign matter, and the like. Instead, if a defect repeats on a wafer in multiple dies on a reticle, the defects on the wafer that repeat in the dies are likely due to an interaction issue between the reticle, wafer, and process (e.g., a marginal design that is failing due to a design/process interaction issue). Such die repeater defects may be interesting in some use cases, and the embodiments described herein may be used for such cases. However, the embodiments described herein can also be used specifically for detecting defects that repeat from printed reticle instance to printed reticle instance and can therefore be assumed to be caused by reticle defects.

In some instances, the defects will not be reported in reticle coordinates by the computer subsystem. In other words, when the computer subsystem detects a defect, the coordinates of the location of that defect may not be determined by the computer subsystem with respect to a reticle. In this manner, the coordinates of the defects determined by the computer subsystem may be translated into reticle coordinates by the computer subsystem or another system or method. The coordinates may be translated in a number of different ways. For example, one relatively straightforward way is to translate the coordinates reported for the defects to a reference that is common to the wafer and the reticle such as a design for the wafer and the reticle. In one such example, the images generated for the defects by the inspection subsystem can be aligned to the design for the wafer. Once the design coordinates of the defects are determined, those coordinates can be translated to reticle coordinates based on the known relationship between the design and the reticle.

The computer subsystem may preferably store information for all of the detected defects such that the information for all of the detected defects is available for repeater defect detection (RDD) and any other functions. Once RDD is performed by the computer subsystem, the information that was stored for defects determined to not be reticle and/or die repeaters may be eliminated from the stored information prior to sending that information to another computer subsystem, another method, back to storage, etc.

The computer subsystem may be configured for storing results of any one or more steps described herein in a computer-readable storage medium. The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc. For example, the computer subsystem may be configured for using information for the defects detected on the reticle to control and/or alter a reticle repair or cleaning process in which the goal is to remove or repair one or more reticle defects to thereby prevent such reticle defects from being printed on other wafers. In one such example, information for the defects detected on the reticle may be used by the computer subsystem described herein, another system (e.g., a reticle repair system (not shown), which may or may not be part of or coupled to the system embodiments described herein), or another method (e.g., a reticle repair method) to determine where on a reticle a repair or cleaning process should be performed. The information for the defects detected on the reticle may also be used to determine one or more parameters of such a process such as the area on which the process is to be performed, the length of time that the process is to be performed, which chemicals or gases should be used in the process, etc. In this manner, the altered reticle can be used to print other wafers in the lithography process. The altered reticle may also be re-inspected using the embodiments described herein at another time after it has been re-introduced to the lithography process.

Any of the changes and/or process parameters determined as described above can then be sent to a semiconductor fabrication system (not shown) or a storage medium (not shown) accessible to the computer subsystem and the semiconductor fabrication system. The semiconductor fabrication system may or may not be part of the system embodiments described herein. For example, the computer subsystem and/or inspection subsystem described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

The embodiments described above have, therefore, a number of advantages over currently used methods and systems for detecting defects on reticles. For example, mask repeater defects cause yield loss on every reticle printed if not detected. With shrinking design rules, repeater defect size that should not be missed is getting smaller. Signals for smaller repeater sizes also get weaker which requires ways to achieve better noise reduction and better nuisance suppression to minimize defect review load. The embodiments described herein provide solutions that meet different user use cases. Some users pursue maximum raw sensitivity to the smallest possible repeaters, while other users may prefer to limit the defect review budget by asking for the smallest total number of repeaters.

The advantages and improvements of the embodiments described herein are provided by a number of new features of the embodiments. For example, the embodiments provide advantages and improvements for suppressing repeating noise in an array region in a couple of ways. First, the embodiments pre-process images received for array print check, by interpolation and/or dynamic compensation, and use those images to generate individual difference images thereby reducing noise in the individual difference images. The embodiments also stack individual difference images, which are then used for defect detection, thereby reducing the repeating noise in the stacked difference images and increasing the SNR of defects and repeating defects. As described further herein, the embodiments are capable of generating an output defect signal with improved quality noticeable in data analysis clouds generated in defect detection.

Each of the embodiments of the system described herein may be combined with any other embodiments of the system described herein.

Another embodiment relates to a computer-implemented method for detecting defects on a reticle. The method includes acquiring images of patterned features formed in an array region on a wafer generated by an inspection subsystem. A reticle is used to print the patterned features on the wafer in a lithography process. The method also includes the interpolating, generating, detecting, and identifying steps described above, which are performed by a computer system coupled to the inspection subsystem.

Each of the steps of the method may be performed as described further herein. The method may also include any other step(s) that can be performed by the inspection subsystem, computer subsystem, and/or system described herein, which may be configured according to any of the embodiments described herein. In addition, the method described above may be performed by any of the system embodiments described herein.

An additional embodiment relates to a non-transitory computer-readable medium storing program instructions executed on a computer system for performing a computer-implemented method for detecting defects on a reticle. One such embodiment is shown in FIG. 9. In particular, as shown in FIG. 9, non-transitory computer-readable medium 900 includes program instructions 902 executable on computer system 904. The computer-implemented method may include any step(s) of any method(s) described herein.

Program instructions 902 implementing methods such as those described herein may be stored on computer-readable medium 900. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMD Extension) or other technologies or methodologies, as desired.

Computer system 904 may be configured according to any of the embodiments described herein.

Further modifications and alternative embodiments of various aspects of the invention will be apparent to those skilled in the art in view of this description. For example, systems and methods for detecting defects on a reticle are provided. Accordingly, this description is to be construed as illustrative only and for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A system configured for detecting defects on a reticle, comprising:
an inspection subsystem configured for generating images of patterned features formed in an array region on a wafer, wherein a reticle is used to print the patterned features on the wafer in a lithography process; and
a computer subsystem configured for:
when a pitch of the patterned features in an instance of a care area in the images is not an integer of pixels in a detector of the inspection subsystem, interpolating a portion of the images in the instance of the care area to generate an interpolated care area image having a modified pitch of the patterned features in the interpolated care area image that is an integer of the pixels;
generating difference images for multiple instances of the care area in the images, wherein generating at least one of the difference images comprises subtracting the interpolated care area image from an additional portion of the images in at least one of the multiple instances of the care area;
stacking the difference images to generate a stacked difference image;
detecting defect candidates in the care area by applying a defect detection method to the stacked difference image; and
identifying defects on the reticle based on the detected defect candidates.

2. The system of claim 1, wherein settings of the inspection subsystem used for said generating the images are not selected based on a pitch of the patterned features on the wafer or the pitch of the patterned features in the images.

3. The system of claim 1, wherein when the pitch of the patterned features in the additional portion of the images is not an integer of the pixels, the computer subsystem is further configured for interpolating the additional portion of the images to generate an additional interpolated care area image having the modified pitch of the patterned features, and wherein generating the at least one of the difference images further comprises subtracting the interpolated care area image from the additional interpolated care area image.

4. The system of claim 1, wherein prior to generating the at least one of the difference images, the computer subsystem is further configured for dynamic compensation of the interpolated care area image to the additional portion of the images.

5. The system of claim 4, wherein the dynamic compensation reduces differences between the interpolated care area image and the additional portion of the images due to color variation on the specimen.

6. The system of claim 4, wherein generating the at least one of the difference images by subtracting the interpolated care area image from the additional portion of the images and the dynamic compensation reduces noise in the at least one of the difference images.

7. The system of claim 4, wherein generating the at least one of the difference images by subtracting the interpolated care area image from the additional portion of the images and the dynamic compensation reduces repeating noise in the stacked difference image.

8. The system of claim 4, wherein generating the at least one of the difference images by subtracting the interpolated care area image from the additional portion of the images and the dynamic compensation increases signal-to-noise ratio of repeating defects in the stacked difference image.

9. The system of claim 1, wherein the multiple instances of the care area correspond to individual cells in the array region.

10. The system of claim 1, wherein the array region is repeating in a first dimension on the wafer, wherein an additional array region is repeating in a second dimension on the wafer orthogonal to the first dimension, wherein the computer subsystem is further configured for separately performing the interpolating, generating, stacking, and detecting steps for the array region and the additional array region, and wherein the interpolating, generating, stacking, and detecting steps are performed for the array region and the additional array region using the images generated in a single pass of the wafer by the inspection subsystem.

11. The system of claim 1, wherein the array region is repeating in a first dimension on the wafer and a second dimension on the wafer orthogonal to the first dimension, wherein generating a second of the difference images comprises subtracting a second care area image in the images for a second of the multiple instances of the care area from the additional portion of the images, wherein the instance of the care area and the at least one of the multiple instances of the care area repeat in the first dimension, and wherein the second of the multiple instances of the care area and the at least one of the multiple instances of the care area repeat in the second dimension.

12. The system of claim 1, wherein the defect detection method determines that a defect candidate is present at a location in the instance of the care area and the at least one of the multiple instances of the care area only when the defect detection method detects the defect candidate at the location in the stacked difference image.

13. The system of claim 1, wherein identifying the defects on the reticle comprises identifying repeater defects on the reticle based on the detected defect candidates.

14. The system of claim 1, wherein identifying the defects on the reticle comprises determining a local image characteristic at a location of one of the detected defect candidates in the images of the multiple instances of the care area, comparing the determined local image characteristic at the location in the images of the multiple instances of the care area to a threshold, determining a number of the images of the multiple instances of the care area having the determined local image characteristic above the threshold, and comparing the determined number to a repeater threshold.

15. The system of claim 1, wherein the patterned features and the inspection subsystem, in combination, cause the images responsive to the patterned features to have repeating and non-constant intensity.

16. The system of claim 1, wherein the array region forms part of a memory device being fabricated on the wafer.

17. The system of claim 1, wherein the inspection subsystem is further configured as a light-based inspection subsystem.

18. The system of claim 1, wherein the inspection subsystem is further configured as an electron beam based inspection subsystem.

19. A non-transitory computer-readable medium, storing program instructions executed on a computer system for performing a computer-implemented method for detecting defects on a reticle, wherein the computer-implemented method comprises:
acquiring images of patterned features formed in an array region on a wafer generated by an inspection subsystem, wherein a reticle is used to print the patterned features on the wafer in a lithography process;
when a pitch of the patterned features in an instance of a care area in the images is not an integer of pixels in a detector of the inspection subsystem, interpolating a portion of the images in the instance of the care area to generate an interpolated care area image having a modified pitch of the patterned features in the interpolated care area image that is an integer of the pixels;
generating difference images for multiple instances of the care area in the images, wherein generating at least one of the difference images comprises subtracting the interpolated care area image from an additional portion of the images in at least one of the multiple instances of the care area;
stacking the difference images to generate a stacked difference image;
detecting defect candidates in the care area by applying a defect detection method to the stacked difference image; and
identifying defects on the reticle based on the detected defect candidates, wherein said acquiring, interpolating, generating, stacking, detecting, and identifying are performed by the computer system coupled to the inspection subsystem.

20. A computer-implemented method for detecting defects on a reticle, comprising:
acquiring images of patterned features formed in an array region on a wafer generated by an inspection subsystem, wherein a reticle is used to print the patterned features on the wafer in a lithography process;
when a pitch of the patterned features in an instance of a care area in the images is not an integer of pixels in a detector of the inspection subsystem, interpolating a portion of the images in the instance of the care area to generate an interpolated care area image having a modified pitch of the patterned features in the interpolated care area image that is an integer of the pixels;
generating difference images for multiple instances of the care area in the images, wherein generating at least one of the difference images comprises subtracting the interpolated care area image from an additional portion of the images in at least one of the multiple instances of the care area;
stacking the difference images to generate a stacked difference image;
detecting defect candidates in the care area by applying a defect detection method to the stacked difference image; and
identifying defects on the reticle based on the detected defect candidates, wherein said acquiring, interpolating, generating, stacking, detecting, and identifying are performed by a computer system coupled to the inspection subsystem.
